(19) United States
(12) Patent Application Publication
(10) Pub. No.: US 2009/0321799 A1
(43) Pub. Date: Dec. 31, 2009

(54) Method and apparatus for increasing conversion gain in imagers

(76) Inventors: Sergey A. Velichko, Boise, ID (US); Gennadiy A. Agranov, Boise, ID (US)

Correspondence Address: DICKSTEIN SHAPIRO LLP, 1825 EYE STREET NW, Washington, DC, 20006-5403, US

(21) Appl. No.: 12/213,835

(22) Filed: Jun. 25, 2008

(51) Int. Cl. H01L 31/00

(52) U.S. Cl. 257/292; 257/E31.001

(57) ABSTRACT

A method, apparatus, and system providing a pixel having increased conversion gain by decreasing the size of an output charge storage region to less than that of a photosensor. A pixel readout is executed by multiple sampling signals based on portions of charge transferred from the photosensor to the storage region and combining the sampled signals in either the analog domain or the digital domain into a representative pixel output signal.

### FIELD OF THE INVENTION

Embodiments of the invention relate generally to the field of CMOS image sensors, and more specifically to a CMOS imager having increased conversion gain, sensitivity and dynamic range.

### BACKGROUND OF THE INVENTION

A complementary metal oxide semiconductor (CMOS) imager includes a focal plane array of pixels. Each pixel includes a photosensor, for example, a photogate, photoconductor or a photodiode, overlying a substrate for producing a photo-generated charge in a doped region of the substrate. Conventionally, each CMOS pixel includes at least a source follower transistor and a row select transistor for coupling the source follower transistor to a column output line. The pixel also typically has a charge storage region, which may be formed as a floating diffusion region, connected to the gate of the source follower transistor. Charge generated by the photosensor is transferred to the floating diffusion region via a transfer transistor. The pixel often also includes a reset transistor for resetting the floating diffusion region to a predetermined charge level.

FIG. 1 illustrates a block diagram of a CMOS imager 208 having a pixel array 200, with each pixel being constructed as described above. Pixel array 200 comprises a plurality of pixels arranged in a predetermined number of columns and rows. The pixels of each row in array 200 are all turned on at the same time by a row select line, and the pixels of each column are selectively output onto output lines by respective column select lines. A plurality of row and column select lines are provided for the entire array 200. The row lines are selectively activated in sequence by a row driver 210 in response to a row address decoder 220 and the column select lines are selectively activated in sequence for each row activated by a column driver 260 incorporated in the column address decoder 270. Thus, a row and column address is provided for each pixel.

The CMOS imager 208 is operated by the control circuit 250, which controls address decoders 220, 270 for selecting the appropriate row and column select lines for pixel integration and readout, and row and column driver circuitry 210, 260, which apply driving voltage to the drive transistors of the selected row and column select lines to carry out various tasks, including, for example, correlated double sampling readout.

In a correlated double sampling readout, the pixel output signals typically include a pixel reset signal, Vrst, sampled from the floating diffusion region after it is reset, and a pixel image signal, Vsig, which is sampled from the floating diffusion region after charges corresponding to an image are transferred to it. The Vrst and Vsig signals are read into a sample-and-hold circuit 265 and are subtracted by a differential amplifier 267 that produces a Vrst−Vsig signal for each pixel, which represents the amount of light impinging on the pixel. This difference signal is digitized by an analog to digital converter 275. The digitized pixel signals are then sent to an image processor 280, which forms and outputs a digital image. The digitizing and image processing can be performed on or off the chip containing the pixel array.

CMOS imagers of the type discussed above are generally known as discussed, for example, in U.S. Pat. No. 6,140,630, U.S. Pat. No. 6,376,868, U.S. Pat. No. 6,310,366, U.S. Pat. No. 6,326,652, U.S. Pat. No. 6,204,524, and U.S. Pat. No. 6,333,205, assigned to Micron Technology, Inc.

FIG. 2 shows a conventional four-transistor CMOS pixel 10. The pixel 10 includes a photosensor 20, e.g., a pinned photodiode, a transfer transistor 30, a reset transistor 40, a source follower transistor 50, a row select transistor 60, a storage region 70, e.g., a floating diffusion region, and an output column line 85. The photosensor 20 is connected to a source/drain terminal of the transfer transistor 30. The state of the transfer transistor 30 is controlled by a signal TX. While the transfer transistor is in an “off” state, charge generated from light impinging upon the photosensor 20 (photo-charge) accumulates within the photosensor 20. When the transfer transistor 30 is switched to an “on” state, the accumulated charge in the photosensor 20 is transferred to the floating diffusion region 70. The storage region 70 is connected to a gate of the source follower transistor 50. The source follower transistor 50 receives an array voltage VaaPix and amplifies the signal received from the storage region 70 for readout onto column line 85. The pixel 10 is selected for readout by a row-select SEL signal, which controls the row select transistor 60. When the row select transistor 60 is switched to an “on” state, the amplified signal from the source follower transistor 50 is transferred to the output column line 85. The storage region 70 may be reset to a known voltage (e.g., VaaPix) by the reset transistor 40 in response to control signal RST, and a reset signal may be read out from the pixel for the correlated double sampling readout as previously described.

A problem common in conventional pixel operation is low conversion gain. Conversion gain represents a relationship of a number of electrons captured to the level of output signal of a pixel. Typically, to maximize overall pixel capacity, the storage region 70 is designed to be nearly equal in electron hole capacity as the photosensor 20. This approximately 1:1 ratio, however, limits the conversion gain. In addition, conversion gain is negatively affected by limitations in the analog chain circuitry after the pixel, which normally limits the pixel output signal swing to approximately 1V.

Another problem common in conventional pixels is dark current. Dark current generally refers to signals generated in an imaging device by a process other than incident light impinging on a pixel's photosensor 20. Such signals can increase the signal representing pixel charge from an individual pixel, which can result in a saturated or bright spot in the output image even when incident light might not otherwise saturate a pixel. Dark current can be generated by silicon surface states, silicon dislocation or metallic contamination, and is aggravated by higher temperatures.

A pixel having low dark current and high conversion gain is desirable, as it would increase the pixel's accuracy and sensitivity, particularly in low light conditions, as well as increase the pixel's dynamic range and signal-to-noise ratio.

### BRIEF DESCRIPTION OF THE DRAWINGS

FIG. 1 shows a block diagram of a conventional CMOS imager.

FIG. 2 shows a schematic diagram of a conventional pixel.

FIG. 3 shows an example of a pixel circuit and parallel correlated double sampling circuits sharing an amplifier circuit in accordance with the disclosed embodiments.

FIG. 4 shows an example of a pixel circuit and parallel correlated double sampling circuits having multiple amplifier circuits with the disclosed embodiments.

FIG. 5A shows a timing diagram for executing a readout of the pixel circuit shown in FIGS. 3 and 4.

FIG. 5B shows another timing diagram for executing a readout of the pixel circuit in FIGS. 3 and 4.

FIG. 6 shows a voltage potential diagram of the pixel circuit during the readout shown in FIG. 5A.

FIG. 7 shows an embodiment of a pixel circuit and a correlated double sampling circuit having an integrating summing circuit.

FIG. 8 shows a timing diagram and potential diagram for executing a readout of the pixel circuit shown in FIG. 7.

FIG. 9 shows an example camera processor system incorporating at least one imaging device constructed in accordance with an embodiment of the disclosure.

### DETAILED DESCRIPTION OF THE INVENTION

In the following detailed description, reference is made to the accompanying drawings, which form a part hereof and illustrate specific embodiments that may be practiced. In the drawings, like reference numerals describe substantially similar components throughout the several views. These embodiments are described in sufficient detail to enable those skilled in the art to practice them, and it is to be understood that other embodiments may be utilized, and that structural, logical and electrical changes may be made.

The term “pixel” refers to a picture element unit cell containing a photo-conversion device and other devices for converting electromagnetic radiation to an electrical signal. For purposes of illustration, a representative pixel is illustrated in the figures and description herein, and typically fabrication of all pixels in an image sensor will proceed simultaneously in a similar fashion.

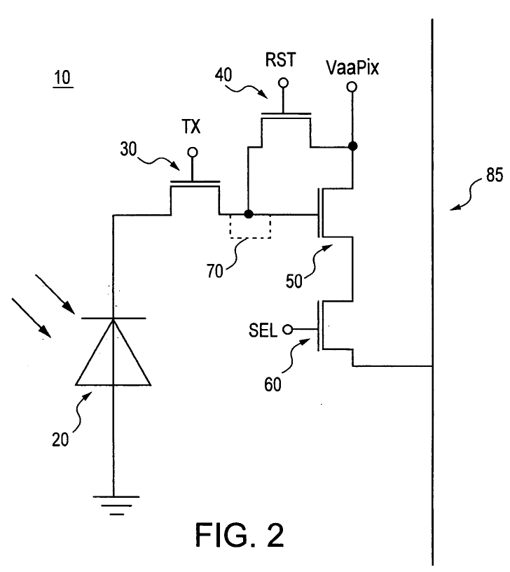

Referring to FIG. 2, by decreasing the size of the floating diffusion region 70, the conversion gain of the pixel 10 is increased. The higher conversion gain effectively increases the pixel's 10 sensitivity to light, thereby increase the dynamic range of the pixel. It also improves the pixel 10 signal-to-noise ratio and decreases the amount of dark current noise the storage region 70 generates.

To compensate for the lower capacity of the storage region 70 and to obtain a readout inclusive of all of the photo-charge accumulated in the photosensor 20, a readout of the pixel array according to disclosed embodiments comprises multiple samplings of signals from each pixel. The multiple sampled signals are then combined into a single representative signal. The sampled signals may be combined in the digital domain, i.e., after having been converted from analog to digital signals, or in the analog domain, i.e., prior to conversion to digital signals.

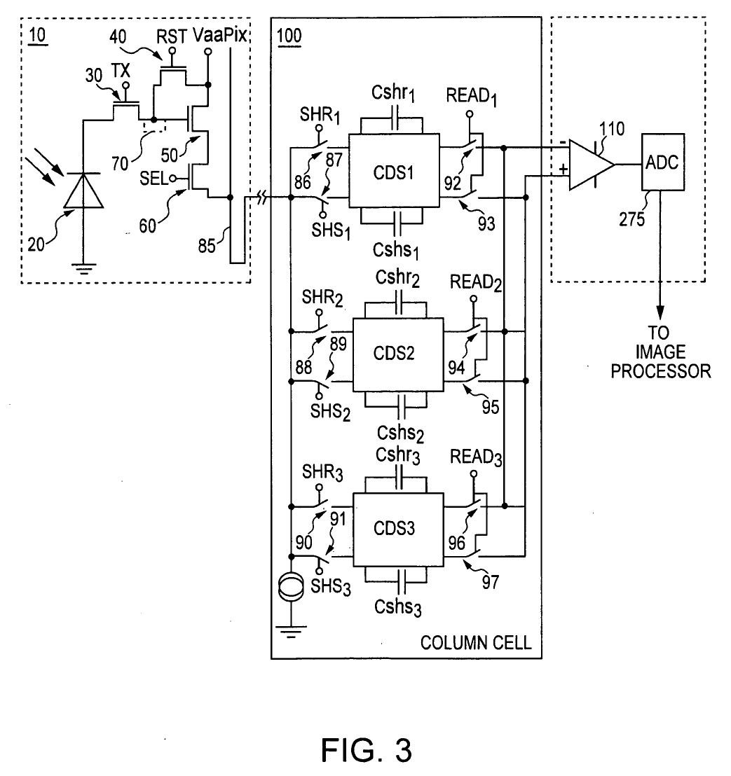

FIG. 3 illustrates an embodiment for multiple readout of signals from pixel 10 and the combining of the readout signals, representative of accumulated photo-charge, in the digital domain after the multiple readouts. The embodiment includes a column cell 100 comprising parallel sampling circuits shown as correlated double sampling circuits CDS1-CDS3. The correlated double sampling circuits CDS1-CDS3 are switchably connected via switches 86-91 to receive multiple sample pixel output signals in the form of a reset signal Vrst and image signal Vsig from a pixel 10 via column line 85 during a readout cycle. Circuits CDS1-CDS3 are switchably connected via switches 92-97 to provide output signals on respective lines which are connected to differential inputs of amplifier 110. The amplifier 110 sequentially amplifies and provides a differential pixel signal from the Vrst and Vsig signal held in each circuit CDS1-CDS3 to an analog-to-digital converter 275. The analog-to-digital converter 275 converts the sequentially applied analog differential signals to digital signals, which are sent to an image processor. The image processor combines the received digital signals into a single representative pixel signal.

Correlated double sampling circuits CDS1-CDS3 respectively comprise capacitors Cshr₁-Cshr₃ and Cshs₁-Cshs₃ for storing the modified sampled reset (Vrst) and image (Vsig) pixel output signals. Such circuits are well known in the art and are not described in great detail herein. The use of correlated double sampling circuits is merely an example as the illustrated embodiment is not limited to any particular type of sampling circuit; any of various known correlated double sampling circuits or other types of sampling circuits may be used. Also, although three sampling circuits CDS1-CDS3 are shown, any number of two or more sampling circuits may be used. Each of the switch pairs SHR₁, SHS₁, SHR₂, SHS₂ and SHR₃, SHS₃ are operated such that a first sampled pair of Vrst, Vsig signals are stored at CDS1, a second sampled pair of Vrst, Vsig signals are stored at CDS2, a third sampled pair of Vrst, Vsig signals are stored at CDS3, and so on.

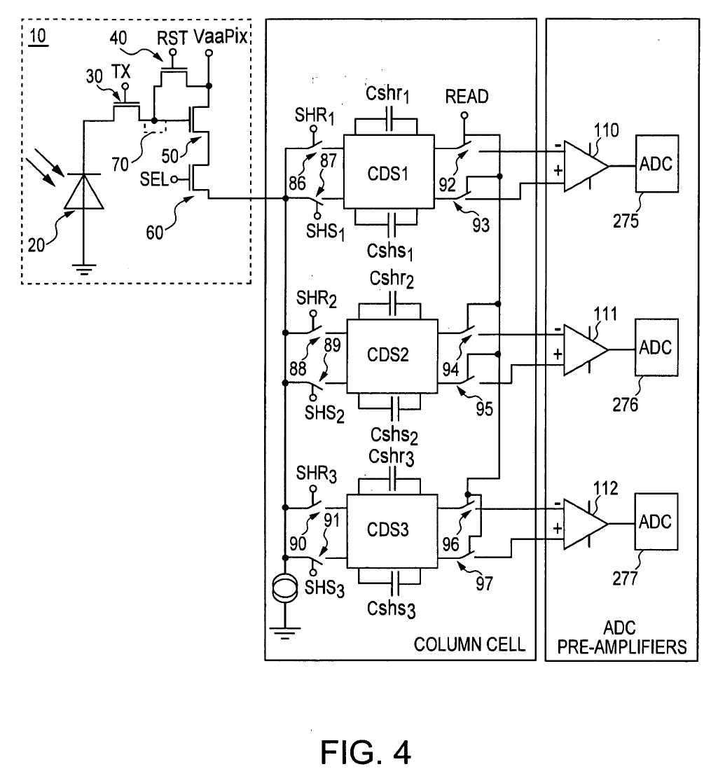

FIG. 4 illustrates an embodiment wherein sampling circuits comprising correlated double sampling circuits CDS1-CDS3 are connected to column line 85 as described above, but each sampling circuit has its outputs connected to a respective differential amplifier 110-112. In this way, multiple analog-to-digital converters 275-277 may be employed to perform simultaneous conversion of the output signals from circuits CDS1-CDS3 to digital form rather than configuring all sampling circuits to share a single analog-to-digital converter. Analog-to-digital converters may therefore be provided individually to each sampling circuit or may be shared by two or more sampling circuits. Furthermore, in any embodiment, analog-to-digital converters may be placed separately as part of each column line 85 circuitry for fast conversion, or be shared among multiple/all column lines 85 to conserve die space. The FIG. 4 embodiment may be used with two or more CDS circuits, similar to the FIG. 3 embodiment.

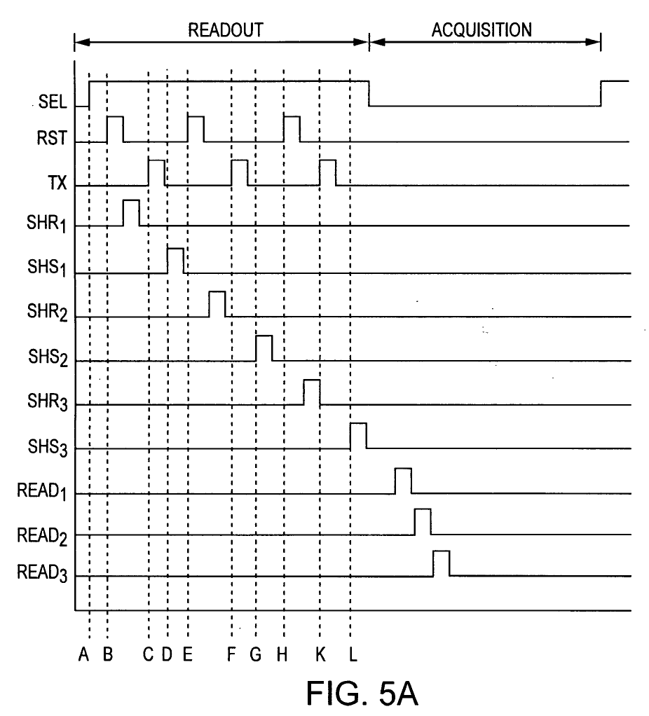

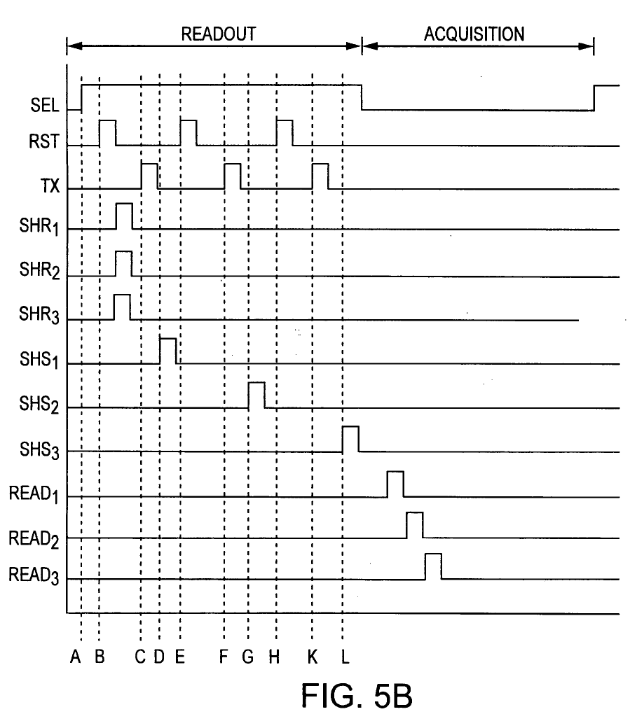

FIG. 5A illustrates one example of a timing diagram of readout and photo-charge acquisition for pixel 10. The illustrated example shows a readout operation; at this point an image signal photo-charge has already been accumulated and stored in the photosensor 20. To begin the readout period, the SEL signal is pulsed high to select a row of pixels for readout by activating row select transistor 60. Next, the reset control signal RST is pulsed to activate the reset transistor 40, resetting the floating diffusion region 70 to the pixel supply voltage VaaPix level. First sample-and-hold reset signal SHR₁ is pulsed to sample a reset signal Vrst from the floating diffusion region 70 (via source-follower 50) on a sample-and-hold capacitor Cshr₁. The transfer control signal TX is then pulsed to activate the transfer transistor 30, allowing signal charge in the photosensor 20 to be transferred to the floating diffusion region 70. Next, a first sample-and-hold pixel signal SHS₁ is pulsed to store a voltage signal Vsig corresponding to the transferred signal charge from the floating diffusion 70 (via source-follower 50) onto sample-and-hold capacitor Cshs₁, completing a first correlated double sampling operation.

Since the floating diffusion 70 has a much smaller charge storage capacity than the photosensor 20, a portion of signal charge may remain in the photosensor 20 after the first sampling depending on the number of accumulated electrons at photosensor 20. To sample any potential remaining charge, while the SEL signal remains high, the reset control signal RST is pulsed a second time to activate the reset transistor 40, again resetting the floating diffusion region 70 to the pixel supply voltage VaaPix level. A second sample-and-hold reset signal SHR₂ is then pulsed to store a reset signal Vrst onto sample-and-hold capacitor Cshr₂ (via source-follower 50). The transfer control signal TX is pulsed to activate transfer transistor 30, allowing another portion of image signal charge from the photosensor 20 to be transferred to the floating diffusion region 70. A second sample-and-hold pixel signal SHS₂ is pulsed to store a voltage signal Vsig corresponding to the transferred portion of signal charge Vsig from the floating diffusion 70 onto sample-and-hold capacitor Cshs₂ via source-follower 50 to complete a second correlated double sampling operation.

Similarly, a third correlated double sampling operation may be executed utilizing the third correlated double sampling circuit CDS3. The SEL signal remains high, and the reset control signal RST is pulsed a third time to activate the reset transistor 30, again resetting the floating diffusion region 70 to the pixel supply voltage VaaPix level. A third sample-and-hold reset signal SHR₃ is pulsed to store a reset signal Vrst onto sample-and-hold capacitor Cshr₃ (via source-follower 50). The transfer control signal TX is pulsed to allow another transfer of image signal charge from the photosensor 20 to the floating diffusion region 70. Next, a third sample-and-hold pixel signal SHS₃ is pulsed to store a voltage signal Vsig corresponding to transferred signal charge Vsig from the pixel 10 onto sample-and-hold capacitor Cshs₃ via source-follower 50, completing a third correlated double sampling.

Although three correlated double sampling operations are shown in FIG. 5A, any number of two or more sampling operations may be executed. Multiple sampling operations may be executed in various ways, for example, by including multiple correlated double sampling circuits as shown in FIGS. 3 and 4, or by repeatedly sampling and digitizing the results of a set number of correlated double sampling circuits.

FIG. 5B shows a readout in which a single reset and sampling operation may be used to obtain a reset signal reference level instead of repeatedly resetting the floating diffusion region 70 and repeatedly obtaining pixel output reset signals for each sampling operation. The SEL signal is pulsed high to select a row of pixels for readout by activating row select transistor 60. Next, the reset control signal RST is pulsed to activate the reset transistor 40, resetting the floating diffusion region 70 to the pixel supply voltage VaaPix level. Sample-and-hold reset signals SHR₁₋₃ are pulsed to sample a reset signal Vrst from the floating diffusion region 70 (via source-follower 50) on a sample-and-hold capacitors Cshr₁₋₃. Thus, the same signal Vrst value is stored and used as a reset signal reference level for all correlated double sampling operations. After obtaining the reset signal reference level, the transfer control signal TX is pulsed to activate the transfer transistor 30, allowing signal charge in the photosensor 20 to be transferred to the floating diffusion region 70. Next, a first sample-and-hold pixel signal SHS₁ is pulsed to store a voltage signal Vsig corresponding to the transferred signal charge from the floating diffusion 70 (via source-follower 50) onto sample-and-hold capacitor Cshs₁, completing a first correlated double sampling operation.

The reset signal reference level is then used to determine a differential signal for the signal charges obtained in the remaining sampling circuits. The readout period ends upon the completion of the final sampling operation.

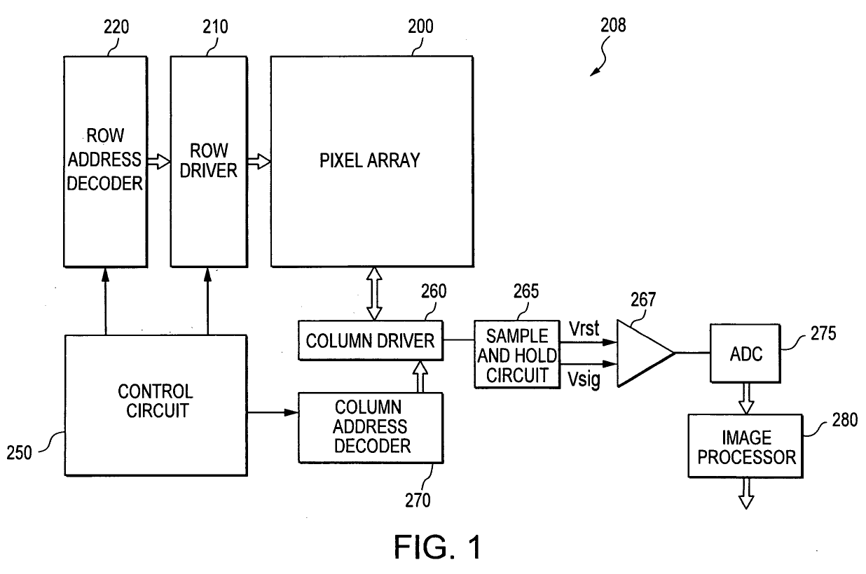

After each pixel readout period, the output signals from each of sampling circuits CDS1-CDS3 are applied to amplifier 110 in the case where the embodiment of FIG. 3 is used, or amplifiers 110-112 in the case of where the embodiment of FIG. 4 is used. The sampling circuit output signals are transferred via switches 92-97, which are controlled by signals READ₁, READ₂, and READ₃ in FIGS. 5A, 5B (or simply the single signal READ in the case of multiple amplifiers 275-277, as shown in FIG. 4). The analog output signals are then converted into digital signals by the analog to digital converter(s) 275 and transferred to image processor 280 (FIG. 1) for combination in the digital domain and further processing.

The method of combining the outputs may comprise, for example, using a counter to count the number of full floating diffusion region 70 transfers that were executed and adding a value representing the remaining charge of the unfilled floating diffusion, or some other type of combination scheme. The embodiments are not limited to any particular combination algorithm.

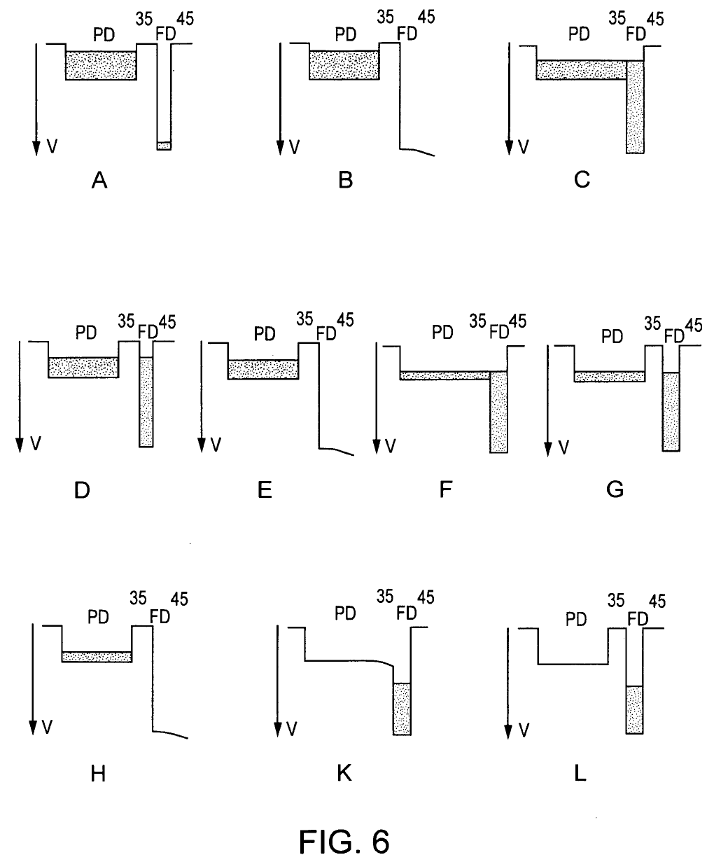

FIG. 6 illustrates voltage potential diagrams of a pixel 10 photosensor 20 well (“PD”), floating diffusion 70 well (“FD”), transfer transistor channel 35, and reset transistor channel 45 for the above described readout. Diagram labels A through L correspond to times A through L marked on the timing diagram shown in FIGS. 5A and 5B.

Time A illustrates potentials of the PD and FD wells before the pixel 10 readout begins. In this example, the PD well already contains accumulated photo-charge and the FD well contains some random amount of charge, which could be charge from the previous pixel readout period and/or dark and/or thermo charges accumulated during the prior acquisition period. At time B, the first RST signal resets the FD well potential to the VaaPix level (shown as V). A reset sample signal SHR samples the reset signal onto the reset signal capacitors in CDS1. Subsequently, at time C, a signal is pulsed to the transfer transistor 30, which opens the transfer transistor channel 35 and, in this example, brings the PD and FD well potentials into an equilibrium state relative to one another. At time D, the transfer transistor channel 35 is closed and, as described above, the FD potential level is output via the source follower transistor 50 and sampled when the SHS₁ signal is pulsed, completing the first sampling operation.

Time E shows the beginning of the next of “n” intermediate sampling operations before the last sampling operation. As shown in FIG. 6, n=1, for a total of three sampling operations, however, it should be understood that any number “n” of multiple intermediate sampling operations before the end sampling operation may be repeated at this point. The RST signal is pulsed at time E, resetting the FD well back to the VaaPix level. As shown in FIG. 5A, the reset signal output from the pixel is sampled onto the reset capacitor of CDS2 by signal SHR₂. At time F, a signal TX is pulsed to transfer transistor 30, opening the transfer transistor channel 35 and bringing the PD and FD well potentials into equilibrium. Next, at time G the transfer transistor channel 35 is closed and, as described above, the FD potential level is output via the source follower transistor 50 and sampled when the SHS₂ signal is pulsed, ending the second sampling. The sampling process shown from time E to time G may be repeated as many times (“n”) as necessary.

At time H the RST signal is pulsed for the last time during the readout, resetting the FD well back to VaaPix level. The reset signal is sampled onto the reset signal capacitor CDS3 by signal SHR₃. At time K a signal is pulsed to transfer transistor 30, opening the transfer transistor channel 35. At this point in the illustrated diagram, the last remaining charges stored in the PD well are transferred to the FD well. It should be fully understood that two or more samples e.g., “n” equal to up to 10 or even hundreds may be used to actually reach this point of final transfer. Following the completion of the final transfer, the last of the photo-charge that was stored in the PD well is transferred to the FD well. At time L, the SHS₃ signal is pulsed, sampling the final FD potential level onto the photo signal capacitor of CDS3 as described above. It should also be understood that if an embodiment employs a set number of repeated samples, e.g., 10, the full amount of photo-charge could be completely sampled after only 4 or 5 samplings. A mechanism may be employed to prevent the continued repeated samplings in the case where the photo-charge is level does not require the full number of samplings. For example, if the sampled signal level after a transfer (TX) operation does not change, then a circuit detecting this may stop further signal readout and sampling from a pixel.

In a typical rolling shutter readout, pixels in the row(s) preceding the row being read out, for example in the manner described above, accumulate charge during an acquisition period. FIG. 5A illustrates a timing diagram for the acquisition period. The reset control signal RST, transfer control signal TX and all sample-and-hold signals SHRₙ, SHSₙ may be set to a ground or near-ground potential during the acquisition period. The photosensor 20 of pixels 10 in the acquisition period row accumulate photo-charge based on the incoming light incident on the photosensor 20. After the acquisition period, a readout period begins. During the readout period, the photo-charges accumulated in the acquisition period are read out of the pixel 10, for example, in the manner described above.

The operation of repeated pixel readout using only one reset signal sample shown in FIG. 5B by the sampling signal SHR causes the sampled reset signal to be applied to the reset capacitors at the same time in all CDS circuits. The analog signal chain (i.e., amplifier 110, ADC 275) gain should be adjusted according to the level of each sampling circuit CDS1-CDS3 output signal. Depending on the fill levels of the respective PD wells, some of the sampling circuits may generate large signals (e.g., when sampling the full FD at time D, FIG. 6) and some sampling circuits may generate small signals (e.g., when sampling the partially filled FD at time K, FIG. 6). Either through the use of simple arbitration logic or auto-gain adjusting amplifier circuitry, the final digital representation of the sampling circuits'CDS1-CDS3 outputs for each pixel 10 should be properly scaled to the same gain, then summed in the digital domain to obtain an accurate digital representation of the pixel 10 photo-charge accumulated during the acquisition period.

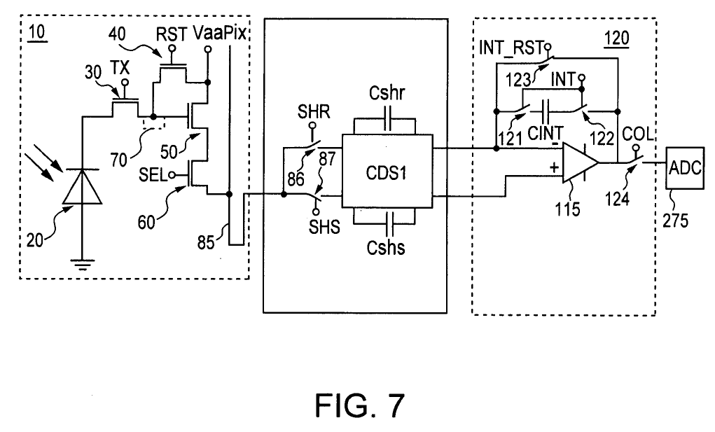

FIG. 7 illustrates an embodiment of a sequential configuration for combining multiple readouts of a pixel 10 in the analog domain. A sampling circuit CDS1 is switchably connected to the column line 85 via switches 86-87, which are controlled by signals SHR and SHS. The sampling circuit provides output signals to an integrated summing circuit 120. The integrated summing circuit 120 comprises an amplifier 115 having a capacitor Cint switchably connected in parallel with the amplifier 115 via switches 121-122, said switched 121-122 being controlled by a signal INT. A switch 123, closed in response to a signal INT_REST, opens or closes a circuit that resets capacitor Cint. The output of the amplifier 115 is switchably connected to an analog-to-digital converter 275 via switch 124, which is controlled by a signal COL.

Generally, in this embodiment one sampling circuit CDS1 is used to read charges from a pixel 10 floating diffusion region 70 a number of times sequentially while a differential amplifier 115 adds a differential output signal of the CDS circuit for each sampling to a charge storage device, e.g., capacitor Cint. The charge storage device Cint, although illustrated as a single capacitor, may be implemented as a multiple-capacitor circuit or as other charge storage devices known in the art.

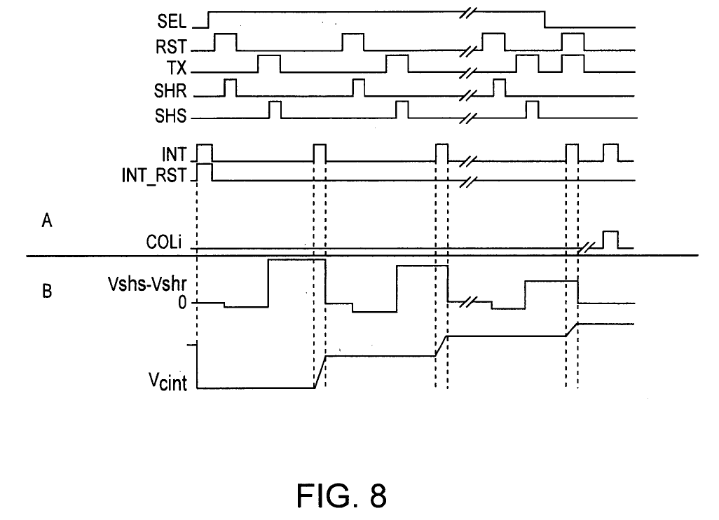

FIG. 8 shows an example of a timing diagram (A) of a readout of the FIG. 7 embodiment using an integrating summing circuit and an accompanying voltage potential diagram (B). Before the readout period begins, INT_RST and INT are pulsed to reset capacitor Cint. The readout period is initiated by pulsing a SEL signal to the select a pixel row for readout. During the first readout period, the reset control signal RST is pulsed to activate the reset transistor 40, resetting the floating diffusion region 70 to the pixel supply voltage VaaPix level. Sample-and-hold reset signal SHR is pulsed next to store the reset signal Vrst onto sample-and-hold capacitor Cshr. The transfer control signal TX is then pulsed to activate the transfer transistor 30, allowing a portion of the accumulated photo-charge in the photosensor 20 to be transferred to the floating diffusion region 70. Next, a sample-and-hold pixel signal SHS is pulsed to store voltage signal Vsig corresponding to the transferred charge from the floating diffusion 70 onto sample-and-hold capacitor Cshs, completing a first correlated double sampling (CDS). Signal INT is pulsed to store CDS1 output signal Vshs−Vshr on capacitor Cint. The stored voltage potential V_{Cint} raises correspondingly to the difference of Vshs−Vshr.

After the first readout is complete, the reset control signal RST is pulsed a second time to activate the reset transistor 40, again resetting the floating diffusion region 70 to the pixel supply voltage VaaPix level. A sample-and-hold reset signal SHR is pulsed next to store a reset signal Vrst onto sample-and-hold capacitor Cshr. The transfer control signal TX is then pulsed to activate transfer transistor 30, transferring another portion of photo-charges from photosensor 20 to the floating diffusion region 70. The sample-and-hold pixel signal SHS is pulsed to sample signal Vsig onto sample-and-hold capacitor Cshs, thereby completing a second correlated double sampling of pixel 10. Signal INT is pulsed to add the correlated double sampling output differential signal Vshs−Vshr to capacitor Cint, raising V_{Cint} to the sum of the Vshs−Vshr difference and the previously stored charge.

The above-described process may be executed repeatedly, sampling and adding the differential output onto capacitor Cint. It should be understood that the sampling and adding process may be executed two or more times and is not limited to any particular number of repetitions. After the sampling repetitions are complete, the charge stored V_{Cint} is a sum total analog representation of the photo-charge accumulated by pixel 10. The row select signal SEL is set low, deselecting the pixel row for readout, and both the floating diffusion region 70 and photosensor 20 are reset by simultaneous pulses of the TX and RST signal in preparation for the next acquisition period. A signal COL is also pulsed simultaneously with the signal INT to transfer the charge stored on V_{Cint} to analog-to-digital converter 275 for conversion to a digital signal. The digitally converted signal is subsequently provided to an image processor for further processing.

During the acquisition period, the reset control signal RST, transfer control signal TX, sample-and-hold signals SHR, SHS, and integration signals INT, INT_RST may be set to a ground potential or near ground potential. For a next frame, the photosensor 20 accumulates integration signal photo-charge based on the light incident on the photosensor 20 during the acquisition period. After the acquisition period, another readout period begins. During the next readout period, the photo-charges accumulated in the acquisition period are read out of the pixel 10, and the above-described process repeats.

In any of the disclosed embodiments, the combination of the floating diffusion region 70 having a lower capacity than that of the photosensor 20 with the multiple readouts greatly increases the pixel 10 conversion gain. The size of the floating diffusion region 70 would determine the limit for the conversion gain. Preferably, the floating diffusion region 70 would be formed having a charge storage capacity that is no more than half the size of the photosensor 20 charge storage capacity, but smaller ratios are possible, e.g., as low as hundreds of times smaller, depending on the allowable limits of the readout circuitry.

By decreasing the floating diffusion region 70 size and increasing the conversion gain, the pixel 10 sensitivity increases. Each captured photo-charge generates a higher signal change referenced to the analog-to-digital converter 275 input. The higher conversion gain also provides better input referenced noise, since the analog signal chain noise portion of the overall noise is inversely proportional to the conversion gain. Thus, the overall pixel 10 signal-to-noise ratio (SNR) improves as well. Furthermore, the above disclosed embodiments are not limited by the source follower 50 and analog signal chain limitations (e.g., signal swing), thereby providing an improved dynamic range.

The embodiments described above are not limited to the circuitry described here. One of ordinary skill in the art, for example, may use only one reset signal sample-and-hold capacitor and do only one reset SHR signal reading and multiple SHS signal readings to save processing time, or combine all sample-and-hold circuitries in a different manner.

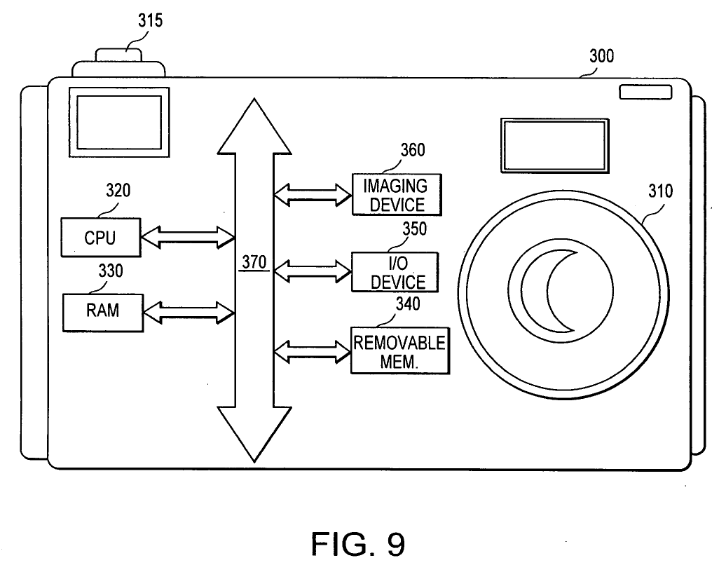

FIG. 9 is a block diagram of a processing system, for example, a camera system 300 having a lens 310 for focusing an image on imaging device 360 when a shutter release button 315 is pressed. Imaging device 360 may be configured as shown in FIG. 1, but including a pixel array 200 constructed incorporating pixels 10 and sampling circuitry in accordance with embodiments of the present invention. Although illustrated as a camera system the system 300 may also be a computer system, a process control system, or any other system employing a processor and associated memory. The system 300 includes a central processing unit (CPU) 320, e.g., a microprocessor, that communicates with the imaging device 360 and one or more I/O devices 350 over a bus 370. It must be noted that the bus 370 may be a series of buses and bridges commonly used in a processor system, but for convenience purposes only, the bus 370 has been illustrated as a single bus. The processor system 300 may also include random access memory (RAM) device 330 and some form of removable memory 340, such a flash memory card, or other removable memory as is well known in the art.

While embodiments have been described in detail, it should be readily understood that they are not limited to the disclosed embodiments. Rather the embodiments can be modified to incorporate any number of variations, alterations, substitutions or equivalent arrangements not heretofore described.

What is claimed as new and desired to be protected by Letters Patent of the United States is:

1. An imager circuit, comprising:
a pixel including a photosensor having a first charge capacity and a storage region having second charge capacity lower than the first charge capacity;
readout circuitry to sample signals corresponding to charge signals from the pixel multiple times during a readout of the pixel; and
a control circuit for operating the pixel and readout circuitry multiple times to transfer charge accumulated by the photosensor during one integration period to the storage region and sample signals based on transferred charge signals from the storage region.

2. The imager circuit of claim 1, wherein the pixel comprises:
a transfer transistor for controlling a transfer of charge between the photosensor and the storage region,
a reset transistor for resetting a charge level on the storage region, and
a source-follower transistor for providing a readout signal based on charge stored in the storage region,

3. The imager circuit of claim 1, wherein the readout circuitry comprises:
at least two sampling circuits, each circuit for sampling a portion of a pixel readout signal; and
a summing circuit for combining the sampled portions of pixel readout signals from the sampling circuits into a pixel output signal.

4. The imager circuit of claim 3, wherein the summing circuit comprises:
at least one amplifier that provides output signals based on the sampled portions;
at least one analog-to-digital converter circuit that receives and converts the output signals from the amplifier into digital signals; and
a processor that combines the digital signals into the single output signal.

5. The imager circuit of claim 4, wherein
each sampling circuit is switchably connected to a respective amplifier; and
each amplifier is connected to a respective analog-to-digital converter circuit.

6. The imager circuit of claim 5, wherein each amplifier is scaled to provide identical gain.

7. The imager circuit of claim 4, wherein
at least two sampling circuits are switchably connected to a single amplifier; and
the amplifier is connected to an analog-to-digital converter circuit.

8. The imager circuit of claim 3, wherein each sampling circuit samples a pixel reset signal portion and a pixel image signal portion.

9. The imager circuit of claim 3, wherein the sampling circuits each sample one and the same pixel reset signal.

10. The imager circuit of claim 1, wherein the storage region has a charge storage capacity that is less than half the photosensor charge storage capacity.

11. The imager readout circuit of claim 3, wherein the summing circuit combines the output signals in the digital domain.

12. An imager circuit, comprising:
a pixel array, including a pixel having a photosensor having a first charge storage capacity size, and a storage region having a second charge storage capacity size, wherein the second charge storage capacity size is less than the first charge storage capacity size; and
a readout circuit comprising:
a sampling circuit that samples signals based on charge in the storage region which was accumulated by the photosensor during an integration period and subsequently transferred to the storage region, and
a summing circuit that combines the sampled signals from the sampling circuit into a single output signal.

13. The imager circuit of claim 12, wherein the summing circuit combines the sampled signals in the analog domain.

14. The imager circuit of claim 12, wherein the summing circuit comprises:
a differential amplifier that receives differential signals from the sampling circuit and provides a differential output signal; and
a storage device switchably connected to receive the differential output signal from the differential amplifier.

15. The imager circuit of claim 14, wherein the storage device comprises at least one capacitor.

16. The imager circuit of claim 12, wherein the sampling circuit comprises a correlated double sampling circuit.

17. The imager circuit of claim 12, wherein the storage region has a capacity less than half the capacity of the photosensor charge storage capacity.

18. A method of operating a pixel, comprising:
accumulating photo-charge in a photosensor in the pixel during an integration period;
transferring a first portion of the photo-charge from the photosensor to a storage region in the pixel;
sampling a signal generated from the first portion of the photo-charge from the storage region;
transferring a second portion of photo-charge from the photosensor to the storage region;
sampling a signal generated from the second portion of photo-charge from the storage region; and
combining the sampled signals into a signal representative of the photo-charge accumulated in the photosensor.

19. The method of claim 18, wherein the sampled signals are combined in the analog domain.

20. The method of claim 18, further comprising sampling a reset signal corresponding to a reset charge on the storage region and wherein the sample steps each comprise a correlated double sampling of a pixel reset signal and a charge transferred from the photosensor.

21. The method of claim 20, wherein the reset signal is sampled once and is used in each of said the correlated double sampling steps.

22. The method of claim 20, wherein each of the sample steps comprise sampling a reset signal corresponding to a reset charge on the storage region and sampling a signal generated from a portion of charge transferred to the storage region.

23. A method of operating a pixel, comprising:
accumulating photo-charge in a photosensor in the pixel during an image acquisition;
transferring a first portion of the photo-charge from the photosensor to a storage region in the pixel;
sampling a first signal generated from the first portion of the photo-charge from the storage region;
transferring the sampled first signal to a summing circuit;
transferring a second portion of photo-charge from the photosensor to the storage region;
sampling a second signal generated from the second portion of photo-charge from the storage region;
transferring the sampled second signal to the summing circuit.

24. The method of claim 23, further comprising summing the first and second sampled signals in the analog domain in the summing circuit.

25. The method of claim 23, wherein each of the sampling steps comprise correlated double sampling.

26. The method of claim 23, further comprising providing an output signal from the summing circuit to an analog-to-digital converter circuit, the output signal being an analog signal representing the total amount of photo-charge that was accumulated in the photosensor.

27. A camera system, comprising:
a lens;
a pixel array for receiving an image through the lens, the pixel array comprising a plurality of pixels, at least one pixel comprising:
a photosensor that generates and accumulates photo-generated charge during an integration period, and
a storage region that repeatedly stores a portion of charge accumulated by the photosensor during the integrated period, the storage region having a charge storage capacity less than the photosensor charge storage capacity,
a sampling circuit that samples signals corresponding to two or more portions of charge transferred from the photosensor and stored in the storage region, and
a summing circuit that combines the sampled signals from the sampling circuits into a single output signal.
